(19) United States
(12) Patent Application Publication
(10) Pub. No.: US 2025/0172155 A1
(43) Pub. Date: May 29, 2025

(54) MULTI FAN DEVICE

(71) Applicant: Purple Cloud Development Pte. Ltd., Singapore (SG)

(72) Inventor: Shiman Xu, Singapore (SG)

(21) Appl. No.: 18/959,859

(22) Filed: Nov. 26, 2024

(30) Foreign Application Priority Data
Nov. 27, 2023 (CN) 202311599331.7

(51) Int. Cl. F04D 25/06; F04D 29/52; H05K 7/20

(52) U.S. Cl. CPC F04D 25/0693; F04D 29/522; H05K 7/20172

(57) ABSTRACT

A multi fan device may include a plurality of fans. Each plurality of fans includes a fan base, fan, connector assembly, fastener assembly, and fan frame. The fan is rotatably coupled to the fan base. The fan frame is coupled to the fan base with the connector assembly and fastener assembly therebetween. The fan frame and the fan base, define a receiving side and a connection side. The receiving side includes a first connector end and first fastener end, and the connection side includes a second connector end and second fastener end. The connector assembly is configured to enable each plurality of fans to electrically couple together at the first connector end and the second connector end via a pushing force. The fastener assembly is configured to enable each plurality of fans to join together at the first fastener end and the second fastener end via an electromagnetic force.

### RELATED APPLICATIONS

This US application claims the benefit of priority to China application no. 202311599331.7, filed on Nov. 27, 2023, of which is incorporated herein by reference in its entirety.

### TECHNICAL FIELD

The present disclosure relates to heat-transfer components and assemblies, and more particularly, but not limited to, multi fan devices.

### BACKGROUND OF THE INVENTION

With increasing processing speed and performance of electronic devices, the amount of heat generated during operation of an electronic device has increased. The heat generation increases the temperature of the electronic device and, if the heat cannot be dissipated effectively, the reliability and performance of the electronic device is reduced. To prevent overheating of an electronic device, cooling systems such as air-cooling systems and liquid cooling systems are used to efficiently dissipate the heat generated by the electronic device and, thereby ensure the standard operation of the electronic device.

In the case of multi fan devices or other rotating cooling apparatuses of air-cooling systems that may be individually stacked and connected together, cables may extend from a back end of each fan and be electrically coupled together, with the stack of fans terminating with a single cable. However, having cables extending from each fan increases the risk for cable damage by users or other electronic components in the electronic device. Meanwhile, if the cables are tidied up, increased time is required for installation of the multi fan devices and additional footprint would still be required for the tidied-up cables. Also, while the individually stacked fans may be fastened together by snap fitting, extended use generally loosens the snap fit connection, which may lead to loose electrical coupling of the fans. Any additional mechanism to secure the snap fit connection would require additional components, increasing the risk for part damage or defect, and further increasing the time required for installation of the multi fan devices.

### SUMMARY OF THE INVENTION

The present disclosure provides a multi fan device with decreased parts, and simplified and secure assembly.

In some aspects, the techniques described herein relate to a multi fan device, including a plurality of fans. Each plurality of fans include a fan base, a fan, a connector assembly, a fastener assembly, and a fan frame. The fan base includes a flange. The fastener assembly is disposed on the fan base and the connector assembly is disposed on the flange. The fan is rotatably coupled to the fan base. The fan frame includes a fan wall. The fan frame is coupled to the fan base with the connector assembly and the fastener assembly, both, respectively between the fan base and the fan frame. The fan wall and the flange, together, define a fan space, where the fan is rotatably coupled to the fan base. The fan frame and the fan base, together, define a receiving side and a connection side. The connection side is opposite the receiving side. The receiving side includes a first connector end and a first fastener end. The connection side includes a second connector end and a second fastener end. The first fastener end is opposite the first connector end. The second fastener end is opposite the second connector end. The connector assembly is configured to enable each plurality of fans to electrically couple together at the first connector end and the second connector end via a pushing force. The fastener assembly is configured to enable each plurality of fans to join together at the first fastener end and the second fastener end via an electromagnetic force.

In some aspects, the techniques described herein relate to a multi fan device, wherein the fan includes a plurality of blades and a fan motor, the plurality of blades extend outward from the fan motor, the fan motor electrically coupled to the connector assembly.

In some aspects, the techniques described herein relate to a multi fan device, wherein the connector assembly includes a connector cable, a first connector component, and a second connector component. The connector cable including a receiving cable end and a connector cable end. The connector cable is electrically coupled to the first connector component at the receiving cable end. The connector cable is electrically coupled to the second connector component at the connector cable end. The first connector component is disposed at the first connector end and the second connector component is disposed at the second connector end.

In some aspects, the techniques described herein relate to a multi fan device, wherein the fan base further includes a base connector hub component, the fan frame further includes a frame connector hub component, and the first connector component includes a shaft connector component. The base connector hub component and the frame connector hub component define a connector core at the first connector end. The shaft connector component is disposed in the connector core.

In some aspects, the techniques described herein relate to a multi fan device, wherein the first connector component further includes a connector positioner, and the fan frame further includes a connector through-hole. The connector positioner is coupled to the shaft connector component and protruding from a surface of the shaft connector component. The connector positioner is disposed through the connector through-hole. In some aspects, the techniques described herein relate to a multi fan device, wherein the connector core includes a round core, and the shaft connector component includes a cylinder shape. In some aspects, the techniques described herein relate to a multi fan device, wherein the connector positioner and the connector through-hole are configured to enable the shaft connector component to slide in the connector core via the connector positioner.

In some aspects, the techniques described herein relate to a multi fan device, wherein the first connector component includes a connector socket, and the second connector component includes a connector plug.

In some aspects, the techniques described herein relate to a multi fan device, wherein the fastener assembly includes a first fastener component and a second fastener component. The first fastener component is disposed at the first fastener end, and the second fastener is component disposed at the second fastener end. In some aspects, the techniques described herein relate to a multi fan device, wherein the first fastener component includes a first disc, and the second fastener component includes a second disc. The first fastener component and the second fastener component, together, are configured to enable each plurality of fans to join together at the first fastener end and the second fastener end via magnetic attraction.

In some aspects, the techniques described herein relate to a multi fan device, wherein the fan base further includes a base connector housing component, and the fan frame further includes a frame connector housing component. The base connector housing component and the frame connector housing component define a connector cavity at the second connector end. The second connector component is disposed in the connector cavity.

In some aspects, the techniques described herein relate to a multi fan device, wherein the fan base further includes a base fastener hub component, the fan frame further includes a frame fastener hub component, and the first fastener component includes a shaft fastener component. The base fastener hub component and the frame fastener hub component define a fastener core at the first fastener end. The shaft fastener component is disposed in the fastener core.

In some aspects, the techniques described herein relate to a multi fan device, wherein the first fastener component further includes a fastener positioner, and the fan frame further includes a fastener through-hole. The fastener positioner is coupled to the shaft fastener component and protruding from a surface of the shaft fastener component. The fastener positioner is disposed through the fastener through-hole. In some aspects, the techniques described herein relate to a multi fan device, wherein the fastener core includes a round core, and the shaft fastener component includes a cylinder shape. In some aspects, the techniques described herein relate to a multi fan device, wherein the fastener positioner and the fastener through-hole are configured to enable the shaft fastener component to slide in the fastener core via the fastener positioner.

In some aspects, the techniques described herein relate to a multi fan device, wherein the fan base further includes a base fastener housing component, and the fan frame further includes a frame fastener housing component. The base fastener housing component and the frame fastener housing component define a fastener cavity at the second fastener end. The second fastener component is disposed in the fastener cavity.

In some aspects, the techniques described herein relate to a multi fan device, further including a fan cable configured to enable power and control signals to be received by each plurality of fans. The fan cable is electrically coupled to the second connector component. In some aspects, the techniques described herein relate to a multi fan device, wherein the plurality of fans include a first plurality of fans, a second plurality of fans, and a last plurality of fans. The first plurality of fans, the second plurality of fans, and the last plurality of fans are linearly disposed together. The fan cable is electrically coupled to the second connector component of the first plurality of fans. The first connector component of the first plurality of fans is electrically coupled to the second connector component of the second plurality of fans, and the first connector component of the second plurality of fans is electrically coupled to the second connector component of the last plurality of fans. In some aspects, the techniques described herein relate to a multi fan device, wherein the plurality of fans include a first plurality of fans, a second plurality of fans, and a last plurality of fans. The first plurality of fans, the second plurality of fans, and the last plurality of fans are linearly disposed together. The first fastener component of the first plurality of fans is fastened to the second fastener component of the second plurality of fans, and the first fastener component of the second plurality of fans is fastened to the second fastener component of the last plurality of fans.

### BRIEF DESCRIPTION OF DRAWINGS

Unless specified otherwise, the accompanying drawings illustrate aspects of the innovative subject matter described herein. Referring to the drawings, wherein like reference numerals indicate similar parts throughout the several views, several examples of multi fan devices incorporating aspects of the presently disclosed principles are illustrated by way of example, and not by way of limitation.

FIG. 1 illustrates a perspective view of a multi fan device, in accordance with various embodiments of the present disclosure.

FIG. 2A illustrates a perspective view of a fan of the multi fan device of FIG. 1, in accordance with various embodiments of the present disclosure.

FIG. 2B illustrates an exploded view of the fan of FIG. 2A, in accordance with various embodiments of the present disclosure.

FIG. 2C illustrates another exploded view of the fan of FIG. 2A, in accordance with various embodiments of the present disclosure.

FIG. 3 illustrates an enlarged partial cross-sectional view of the fan of FIGS. 2A to 2C, in accordance with various embodiments of the present disclosure.

FIG. 4 illustrates another enlarged partial cross-sectional view of the fan of FIGS. 2A to 2C, in accordance with various embodiments of the present disclosure.

FIG. 5 illustrates a perspective view of an alternative multi fan device, in accordance with various embodiments of the present disclosure.

FIG. 6 illustrates another partial internal view of the fan of FIGS. 2A to 2C, in accordance with various embodiments of the present disclosure.

FIG. 7 illustrates a partial internal view of the fan of FIGS. 2A to 2C, in accordance with various embodiments of the present disclosure.

FIG. 8 illustrates a partial internal cross-sectional view of the multi fan device of FIGS. 1, in accordance with various embodiments of the present disclosure.

### DETAILED DESCRIPTION

The following describes various principles related to components and assemblies for electronic devices cooling by way of reference to specific examples of multi fan devices, including specific arrangements and examples of fans embodying innovative concepts. More particularly, but not exclusively, such innovative principles are described in relation to selected examples of connector assemblies and fastener assemblies, and well-known functions or constructions are not described in detail for purposes of succinctness and clarity. Nonetheless, one or more of the disclosed principles can be incorporated in various other embodiments of connector assemblies and fastener assemblies to achieve any of a variety of desired outcomes, characteristics, and/or performance criteria.

Thus, connector assemblies and fastener assemblies having attributes that are different from those specific examples discussed herein can embody one or more of the innovative principles, and can be used in applications not described herein in detail. Accordingly, embodiments of connector assemblies and fastener assemblies not described herein in detail also fall within the scope of this disclosure, as will be appreciated by those of ordinary skill in the relevant art following a review of this disclosure.

Example embodiments as disclosed herein are directed to multi fan devices that can be used in cooling systems to dissipate high heat loads. The multi fan devices may be configured on a chassis, within a chassis, or as part of an electronics system that includes heat producing electronic components to be cooled. The cooling system includes at least one multi fan device. The multi fan device may be coupled to the chassis via a fastener (e.g., bolts, screws, etc.), transporting air to heat producing electronic components to be cooled and/or to an outside of the chassis or electronics system. The multi fan devices may be coupled to the back end of a radiator via a fastener at structural portions of the radiator, transporting air through the radiator to an air plenum or to the outside of the chassis or electronics system.

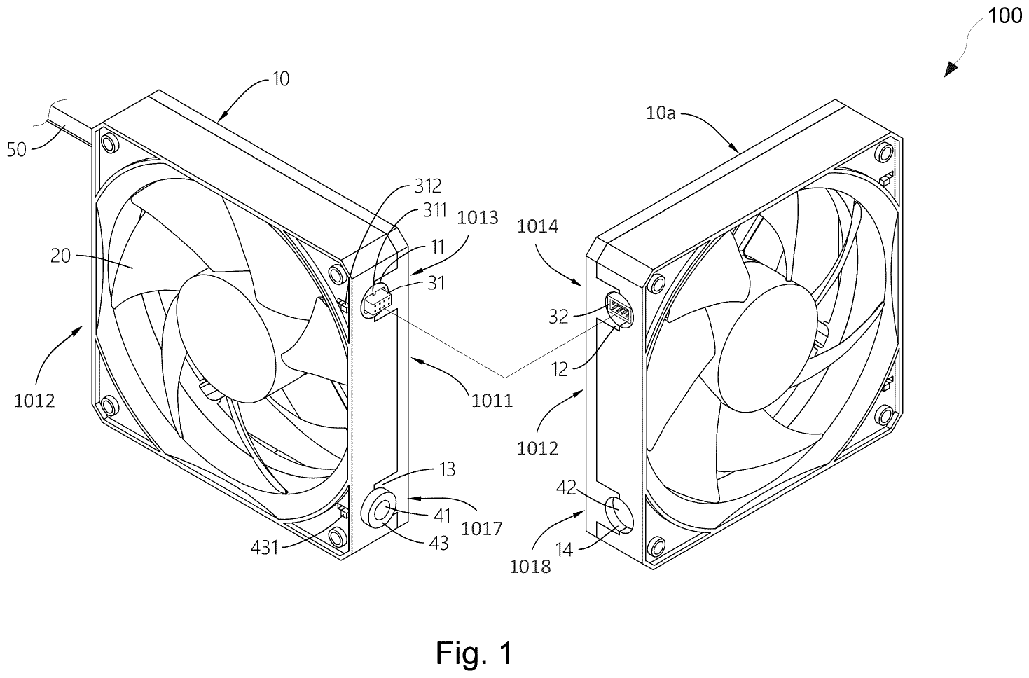

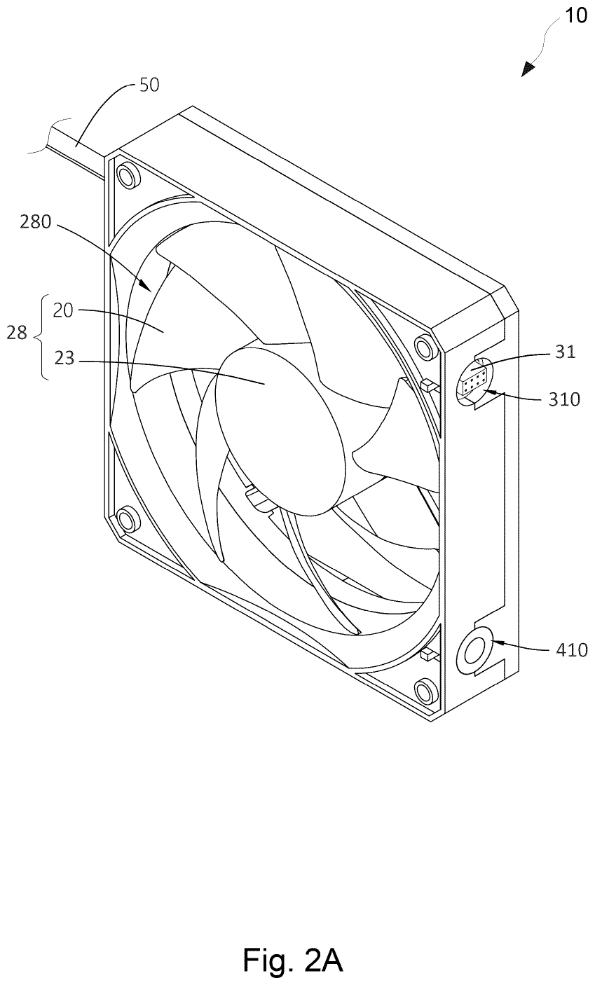

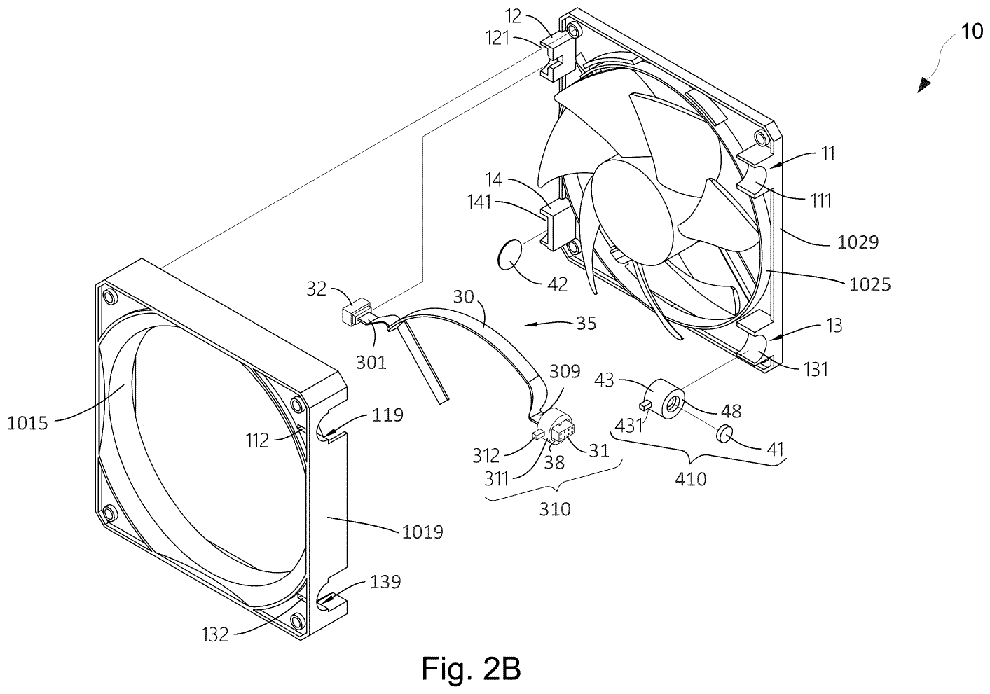

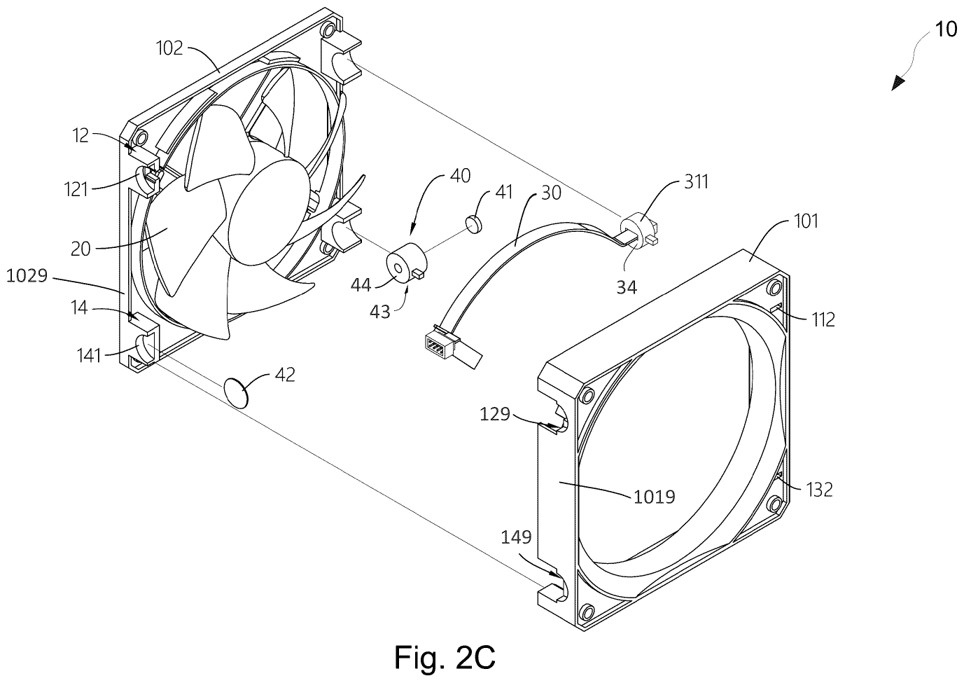

FIGS. 1, 2A, 2B, and 2C illustrate a multi fan device 100, in accordance with various embodiments of the present disclosure. In some embodiments, the multi fan device 100, includes a plurality of fans 10, 10a, 10b. Each plurality of fans 10, 10a, 10b include a fan base 102, a fan 28, a connector assembly 35, a fastener assembly 410/140, and a fan frame 101. The fan base 102 includes a flange 1025. The fastener assembly 410/140 is disposed on the fan base 102 and the connector assembly 35 is disposed on the flange 1025. The fan 28 is rotatably coupled to the fan base 102. The fan frame 101 includes a fan wall 1015. The fan frame 101 is coupled to the fan base 102 with the connector assembly 35 and the fastener assembly 410/140, both, respectively between the fan base 102 and the fan frame 101. The fan wall 1015 and the flange 1025, together, define a fan space 280, where the fan 28 is rotatably coupled to the fan base 102. The fan frame 101 and the fan base 102, together, define a receiving side 1011 and a connection side 1012. The connection side 1012 is opposite the receiving side 1011. The receiving side 1011 includes a first connector end 1013 and a first fastener end 1017. The connection side 1012 includes a second connector end 1014 and a second fastener end 1018. The first fastener end 1017 is opposite the first connector end 1013. The second fastener end 1018 is opposite the second connector end 1014. The connector assembly 35 is configured to enable each plurality of fans 10, 10a, 10b to electrically couple together at the first connector end 1013 and the second connector end 1014 via a pushing force. The fastener assembly 410/140 is configured to enable each plurality of fans 10, 10a, 10b to join together at the first fastener end 1017 and the second fastener end 1018 via an electromagnetic force.

In some embodiments, the fan includes a plurality of blades 20 and a fan motor 23, the plurality of blades 20 extend outward from the fan motor 23, the fan motor 23 electrically coupled to the connector assembly 35. In some embodiments, the connector assembly 35 includes a connector cable 30, a first connector component 310, and a second connector component 32. The connector cable 30 including a receiving cable end 309 and a connector cable end 301. The connector cable 30 is electrically coupled to the first connector component 310 at the receiving cable end 309. The connector cable 30 is electrically coupled to the second connector component 32 at the connector cable end 301. The first connector component 310 is disposed at the first connector end 1013 and the second connector component 32 is disposed at the second connector end 1014.

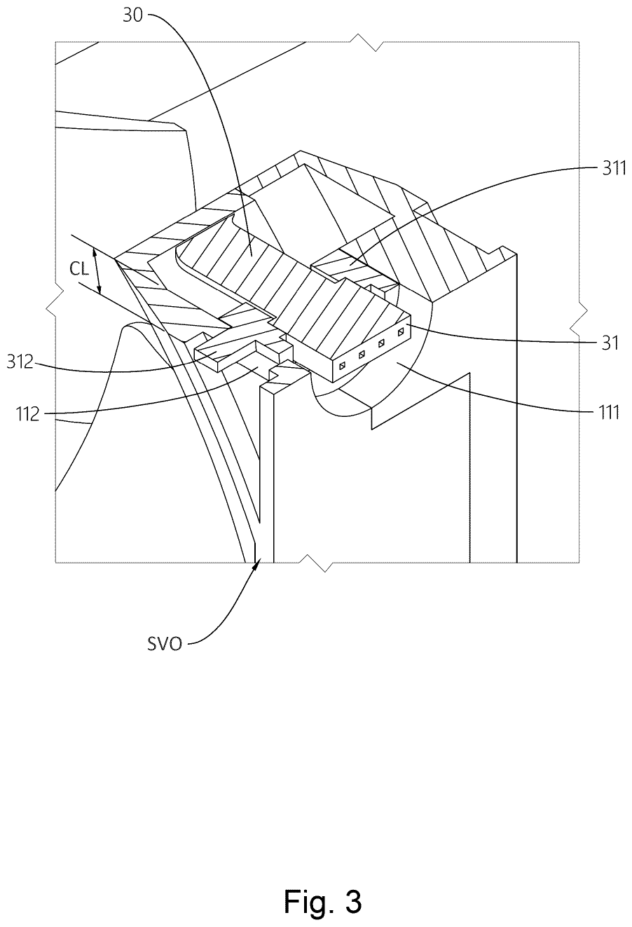

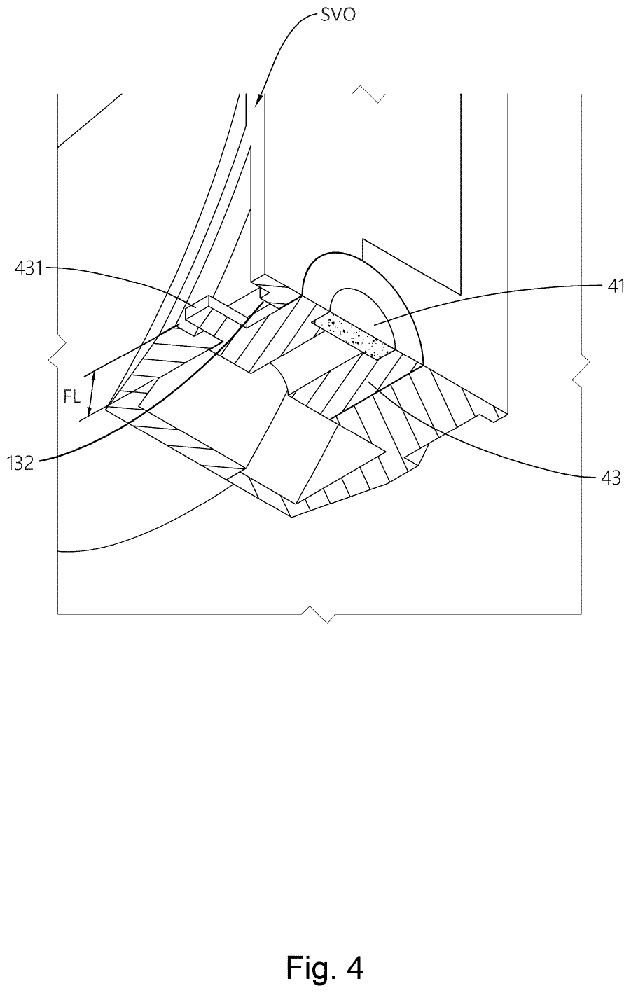

FIGS. 3, and 4 illustrate enlarged partial cross-sectional views of the fan 28, in accordance with various embodiments of the present disclosure. In some embodiments, the fan base 102 further includes a base connector hub component 11, the fan frame 101 further includes a frame connector hub component 119, and the first connector component 310 includes a shaft connector component 311. The base connector hub component 11 and the frame connector hub component 119 define a connector core 111 at the first connector end 1013. The shaft connector component 311 is disposed in the connector core 111.

In some embodiments, the first connector component 310 further includes a connector positioner 312, and the fan frame 101 further includes a connector through-hole 112. The connector positioner 312 is coupled to the shaft connector component 311 and protrudes from a surface of the shaft connector component 311. The connector positioner 312 is disposed through the connector through-hole 112. In some embodiments, the connector positioner 312 includes a connector length CL. The connector length CL does not extend beyond a side view outline SVO of the fan 28. In some embodiments, the connector core 111 includes a round core, and the shaft connector component 311 includes a cylinder shape. In some embodiments, the connector positioner 312 and the connector through-hole 112 are configured to enable the shaft connector component 311 to slide in the connector core 111 via the connector positioner 312. In some embodiments, the first connector component 310 and the second connector component 32 are respectively push-pull connector components. In some embodiments, the first connector component 310 includes a connector socket 31, and the second connector component 32 includes a connector plug.

In some embodiments, the fastener assembly 410/140 includes a first fastener component 410 and a second fastener component 42. The first fastener component 410 is disposed at the first fastener end 1017, and the second fastener component 42 is disposed at the second fastener end 1018. In some embodiments, the first fastener component 410 includes a first disc 41, and the second fastener component 42 includes a second disc. The first fastener component 410 and the second fastener component 42, together, are configured to enable each plurality of fans 10, 10a, 10b to join together at the first fastener end 1017 and the second fastener end 1018 via magnetic attraction. In some embodiments, the first fastener component 410 includes a magnet and the second fastener component 42 includes a magnet, in some embodiments, the first fastener component 410 includes a magnet and the second fastener component 42 includes a ferromagnetic metal, and in some embodiments, the first fastener component 410 includes a ferromagnetic metal and the second fastener component 42 includes a magnet. The ferromagnetic metal can be an iron metal.

In some embodiments, the fan base 102 further includes a base connector housing component 12, and the fan frame 101 further includes a frame connector housing component 129. The base connector housing component 12 and the frame connector housing component 129 define a connector cavity 121 at the second connector end 1014. The second connector component 32 is disposed in the connector cavity 121.

In some embodiments, the fan base 102 further includes a base fastener hub component 13, the fan frame 101 further includes a frame fastener hub component 139, and the first fastener component 410 includes a shaft fastener component 43. The base fastener hub component 13 and the frame fastener hub component 139 define a fastener core 131 at the first fastener end 1017. The shaft fastener component 43 is disposed in the fastener core 131.

In some embodiments, the first fastener component 410 further includes a fastener positioner 431, and the fan frame 101 further includes a fastener through-hole 132. The fastener positioner 431 is coupled to the shaft fastener component 43 and protrudes from a surface of the shaft fastener component 43. The fastener positioner 431 is disposed through the fastener through-hole 132. In some embodiments, the fastener positioner 431 includes a fastener length FL. The fastener length FL does not extend beyond a side view outline SVO of the fan 28. In some embodiments, the fastener length FL and the connector length CL are the same lengths. In some embodiments, the fastener core 131 includes a round core, and the shaft fastener component 43 includes a cylinder shape. In some embodiments, the fastener positioner 431 and the fastener through-hole 132 are configured to enable the shaft fastener component 43 to slide in the fastener core 131 via the fastener positioner 431.

In some embodiments, the fan base 102 further includes a base fastener housing component 14, and the fan frame 101 further includes a frame fastener housing component 149. The base fastener housing component 14 and the frame fastener housing component 149 define a fastener cavity 141 at the second fastener end 1018. The second fastener component 42 is disposed in the fastener cavity 141.

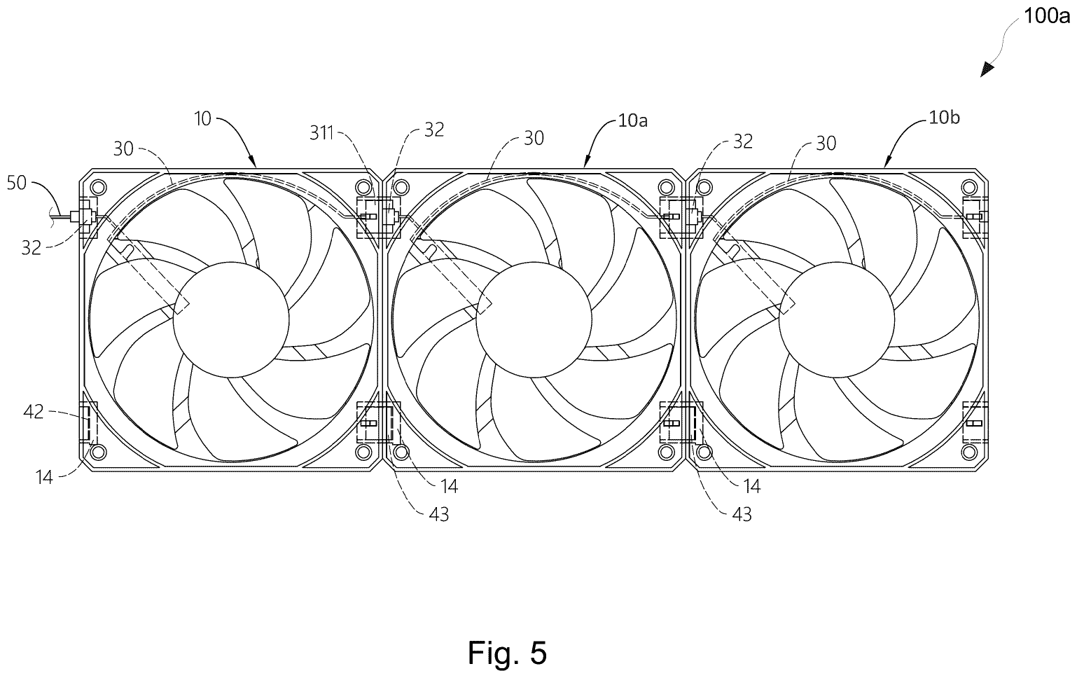

FIG. 5 illustrates another multi fan device 100a, in accordance with various embodiments of the present disclosure. In some embodiments, the multi fan device 100, further including a fan cable 50 configured to enable power and control signals to be received by each plurality of fans 10, 10a, 10b. The fan cable 50 is electrically coupled to the second connector component 32. In some embodiments, the plurality of fans 10, 10a, 10b include a first plurality of fans 10, a second plurality of fans 10a, and a last plurality of fans 10b. The first plurality of fans 10, the second plurality of fans 10a, and the last plurality of fans 10b are linearly disposed together. The fan cable 50 is electrically coupled to the second connector component 32 of the first plurality of fans 10. The first connector component 310 of the first plurality of fans 10 is electrically coupled to the second connector component 32 of the second plurality of fans 10a, and the first connector component 310 of the second plurality of fans 10a is electrically coupled to the second connector component 32 of the last plurality of fans 10b. In some embodiments, the first fastener component 410 of the first plurality of fans 10 is fastened to the second fastener component 42 of the second plurality of fans 10a, and the first fastener component 410 of the second plurality of fans 10a is fastened to the second fastener component 42 of the last plurality of fans 10b.

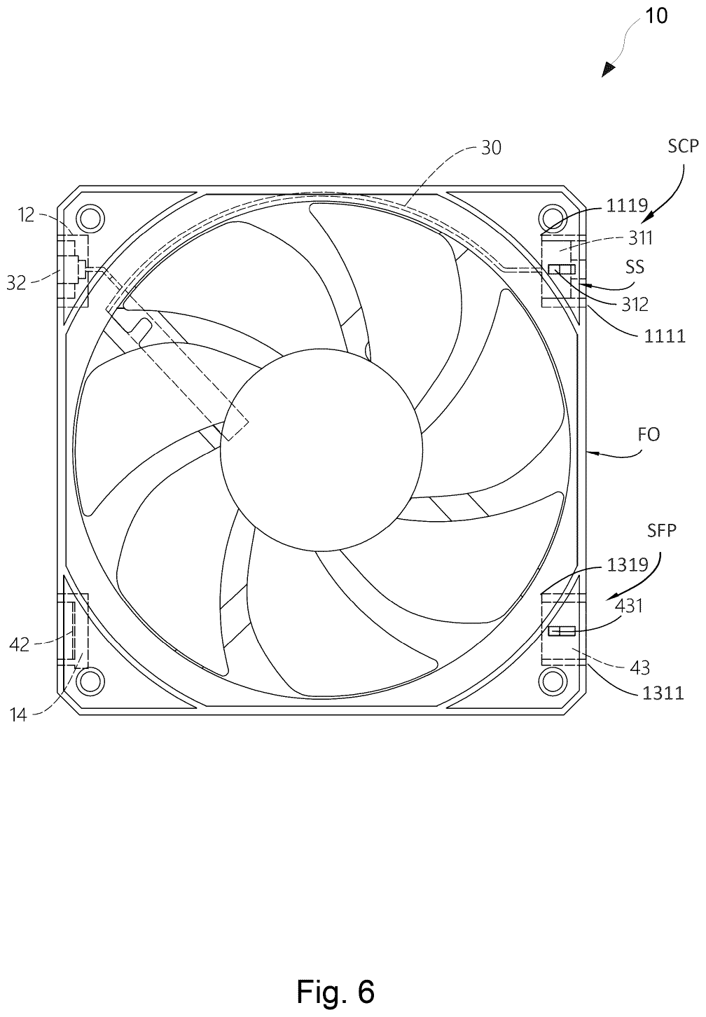

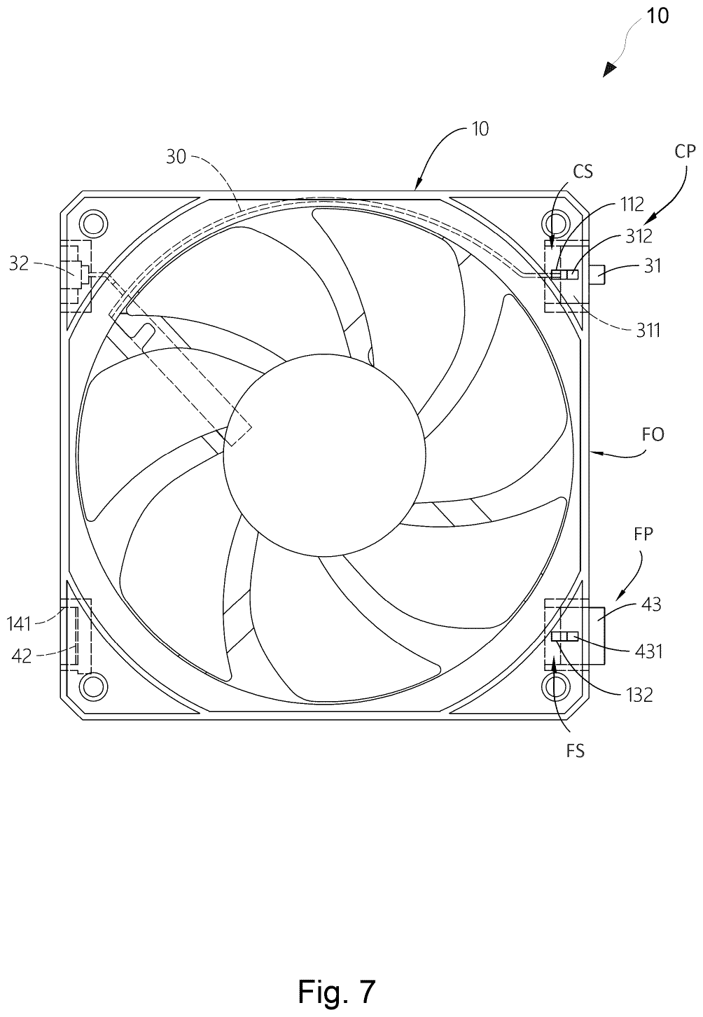

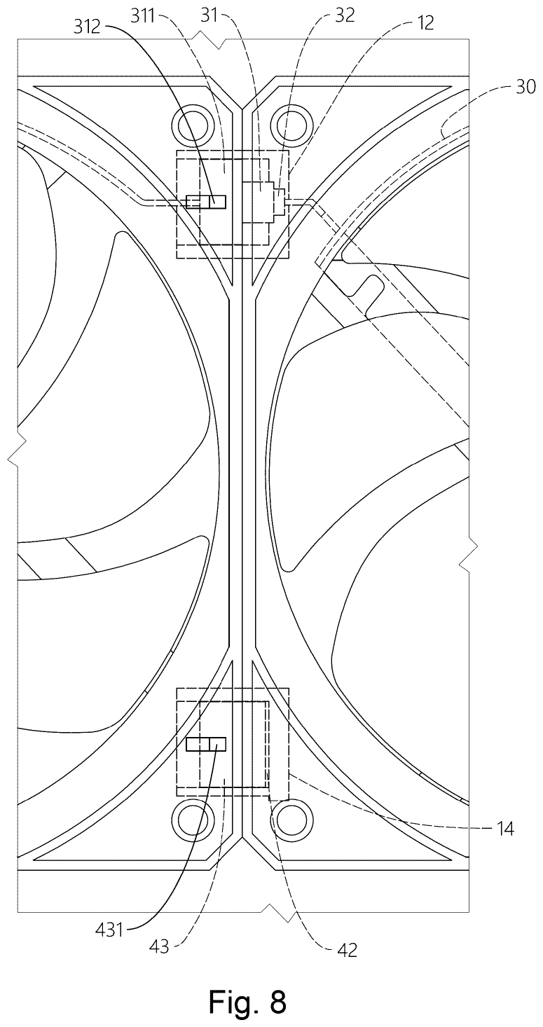

FIGS. 6, 7, and 8 illustrate partial internal views of the multi fan device 100, in accordance with various embodiments of the present disclosure. In some embodiments, the shaft connector component 311 includes a connector back side 34, a connector front side 38, a stored connected position SCP, and a connected position CP, and the connector core 111 includes a stored connector edge 1119 and a connector edge 1111. The stored connector edge 1119 opposite the connector edge 1111. The frame outline FO includes the connector edge 1111. In the stored connected position SCP, the shaft connector component 311 is stored in the connector core 111, with the connector back side 34 positioned linearly to the stored connector edge 1119. When the shaft connector component 311 is stored in the connector core 111, with the connector back side 34 positioned linearly to the stored connector edge 1119, a stored space SS is defined in the connector core 111 between the connector front side 38 and the connector edge 1111. In the connected position CP, the shaft connector component 311 is slid to the connected position CP in the connector core 111, and the connector socket 31 protrudes through to an exterior of the frame outline FO. When the shaft connector component 311 is slid to the connected position CP in the connector core 111, a connected space CS is defined in the connector core 111 between the connector back side 34 and the stored connector edge 1119, and the connector socket 31 protrudes through to an interior of a frame outline FO of the second plurality of fans 10a or the last plurality of fans 10b to fasten and join to a second connector component 32 of the second plurality of fans 10a or the last plurality of fans 10b.

In some embodiments, the shaft fastener component 43 includes a fastener back side 44, a fastener front side 48, a stored fastened position SFP, and a fastened position FP, and the fastener core 131 includes a stored fastener edge 1319 and a front edge 1311. The stored fastener edge 1319 opposite the front edge 1311. The frame outline FO includes the front edge 1311. In the stored fastened position SFP, the shaft fastener component 43 is stored in the fastener core 131, with the fastener back side 44 positioned linearly to the stored fastener edge 1319. In the fastened position FP, the shaft fastener component 43 is slid to a fastened position FP in the fastener core 131, and the fastener front side 48 protrudes through to an exterior of the frame outline FO. When the shaft fastener component 43 is slid to the fastened position FP in the fastener core 131, a fastened space FS is defined in the fastener core 131 between the fastener back side 44 and the stored fastener edge 1319, and the fastener front side 48 protrudes through to an interior of a frame outline FO of the second plurality of fans 10a or the last plurality of fans 10b to fasten and join to a second fastener component 42 of the second plurality of fans 10a or the last plurality of fans 10b.

The connector assembly 35 and the fastener assembly 410/140 with decreased parts provide quick, easy, and secure electrical coupling of each plurality of fans 10, 10a, 10b of the multi fan device 100 of the embodiments. To begin, the connector assembly 35 eliminates cables which extend from each fan for electrically coupling each fan of the multi fan device 100 together in series. Thus, the risk for cable damage by users or other electronic components in an electronic device is removed. Moreover, the connector length CL and the fastener length FL, both, respectively do not extend beyond the side view outline SVO of the fan 28. Also, whether in the stored connected position SCP or electrically coupled in the connected position CP or whether in the stored fastened position SFP or fastened and joined in the fastened position FP, the connector assembly 35 and the fastener assembly 410/140, both, respectively, do not extend beyond the exterior of the frame outline FO without protruding through to an interior of the frame outline FO of the second plurality of fans 10a or the last plurality of fans 10b. Thus, the fans of the multi fan device 100 of the embodiments electrically couple together and fasten and join together without adding any additional footprint to each plurality of fans 10, 10a, 10b. Thus, space is saved and risks of damage is minimized. Furthermore, the push-pull connection between the first connector component 310 and the second connector component 32, and the electromagnetic fastening between the first fastener component 410 and the second fastener component 42, respectively, electrically couple and fasten and join each plurality of fans 10, 10a, 10b together, eliminating snap fit connections, which eliminates the risk for loose electrical coupling of each plurality of fans 10, 10a, 10b due to loosened connections over extended use. Even furthermore, the first connector component 310 disposed at the first connector end 1013 and the second connector component 32 disposed at the second connector end 1014, and at opposite respective ends, the first fastener component 410 disposed at the first fastener end 1017 and the second fastener component 42 disposed at the second fastener end 1018, increases the stability and strength of the push-pull connection and the electromagnetic fastening of each plurality of fans 10, 10a, 10b, thus, even further eliminating the risk for loose electrical coupling of each plurality of fans 10, 10a, 10b due to loosened connections. A multi fan device 100 with decreased parts, and simplified and secure assembly via push-pull connection between the first connector component 310 and the second connector component 32, and electromagnetic fastening between the first fastener component 410 and a second fastener component 42 are provided.

Therefore, embodiments disclosed herein are well adapted to attain the ends and advantages mentioned as well as those that are inherent therein. The particular embodiments disclosed above are illustrative only, as the embodiments disclosed may be modified and practiced in different but equivalent manners apparent to those of ordinary skill in the relevant art having the benefit of the teachings herein. Furthermore, no limitations are intended to the details of construction or design herein shown, other than as described in the claims below. It is therefore evident that the particular illustrative embodiments disclosed above may be altered, combined, or modified and all such variations are considered within the scope and spirit of the present disclosure. The embodiments illustratively disclosed herein suitably may be practiced in the absence of any element that is not specifically disclosed herein and/or any optional element disclosed herein. While compositions and methods are described in terms of “comprising,” “containing,” or “including” various components or steps, the compositions and methods can also “consist essentially of” or “consist of” the various components and steps. All numbers and ranges disclosed above may vary by some number. Whenever a numerical range with a lower limit and an upper limit is disclosed, any number and any included range falling within the range is specifically disclosed. In particular, every range of values (of the form, “from about a to about b,” or, equivalently, “from approximately a to b,” or, equivalently, “from approximately a-b”) disclosed herein is to be understood to set forth every number and range encompassed within the broader range of values. Also, the terms in the claims have their plain, ordinary meaning unless otherwise explicitly and clearly defined by the patentee. Moreover, the indefinite articles “a” or “an,” as used in the claims, are defined herein to mean one or more than one of the elements that it introduces.

1. A multi fan device, comprising:
a plurality of fans;
wherein each plurality of fans comprise:
a fan base including a flange;
a fan rotatably coupled to the fan base;
a connector assembly, the connector assembly disposed on the flange;
a fastener assembly, the fastener assembly disposed on the fan base; and
a fan frame including a fan wall, the fan frame coupled to the fan base, the connector assembly and the fastener assembly, both, respectively between the fan base and the fan frame;
wherein the fan wall and the flange, together, define a fan space, and the fan is rotatably coupled to the fan base in the fan space; and
wherein the fan frame and the fan base, together, define a receiving side and a connection side, the connection side opposite the receiving side, the receiving side including a first connector end and a first fastener end, the connection side including a second connector end and a second fastener end, the first fastener end opposite the first connector end, the second fastener end opposite the second connector end; and
wherein the connector assembly is configured to enable each plurality of fans to electrically couple together at the first connector end and the second connector end via a pushing force; and
wherein the fastener assembly is configured to enable each plurality of fans to join together at the first fastener end and the second fastener end via an electromagnetic force.

2. The multi fan device of claim 1, wherein the connector assembly comprises a connector cable, a first connector component, and a second connector component, the connector cable including a receiving cable end and a connector cable end, the connector cable electrically coupled to the first connector component at the receiving cable end, the connector cable electrically coupled to the second connector component at the connector cable end, the first connector component disposed at the first connector end, the second connector component disposed at the second connector end.

3. The multi fan device of claim 2, wherein the fan base further comprises a base connector housing component, and wherein the fan frame further comprises a frame connector housing component, the base connector housing component and the frame connector housing component define a connector cavity at the second connector end, the second connector component disposed in the connector cavity.

4. The multi fan device of claim 2, wherein the first connector component comprises a connector socket, and wherein the second connector component comprises a connector plug.

5. The multi fan device of claim 2, wherein the fan base further comprises a base connector hub component, and wherein the fan frame further comprises a frame connector hub component, and wherein the first connector component comprises a shaft connector component, the base connector hub component and the frame connector hub component define a connector core at the first connector end, the shaft connector component disposed in the connector core.

6. The multi fan device of claim 5, wherein the first connector component further comprises a connector positioner, and wherein the fan frame further comprises a connector through-hole, the connector positioner coupled to the shaft connector component, the connector positioner protruding from a surface of the shaft connector component and disposed through the connector through-hole.

7. The multi fan device of claim 6, wherein the connector positioner and the connector through-hole are configured to enable the shaft connector component to slide in the connector core via the connector positioner.

8. The multi fan device of claim 7, wherein the connector core comprises a round core, and wherein the shaft connector component comprises a cylinder shape.

9. The multi fan device of claim 1, wherein the fastener assembly comprises a first fastener component and a second fastener component, the first fastener component disposed at the first fastener end, the second fastener component disposed at the second fastener end.

10. The multi fan device of claim 9, wherein the fan base further comprises a base fastener housing component, and wherein the fan frame further comprises a frame fastener housing component, the base fastener housing component and the frame fastener housing component define a fastener cavity at the second fastener end, the second fastener component disposed in the fastener cavity.

11. The multi fan device of claim 9, wherein the first fastener component comprises a first disc, and wherein the second fastener component comprises a second disc, the first fastener component and the second fastener component, together, are configured to enable each plurality of fans to join together at the first fastener end and the second fastener end via magnetic attraction.

12. The multi fan device of claim 9, wherein the fan base further comprises a base fastener hub component, and wherein the fan frame further comprises a frame fastener hub component, and wherein the first fastener component comprises a shaft fastener component, the base fastener hub component and the frame fastener hub component define a fastener core at the first fastener end, the shaft fastener component disposed in the fastener core.

13. The multi fan device of claim 12, wherein the first fastener component further comprises a fastener positioner, and wherein the fan frame further comprises a fastener through-hole, the fastener positioner coupled to the shaft fastener component, the fastener positioner protruding from a surface of the shaft fastener component and disposed through the fastener through-hole.

14. The multi fan device of claim 13, wherein the fastener positioner and the fastener through-hole are configured to enable the shaft fastener component to slide in the fastener core via the fastener positioner.

15. The multi fan device of claim 14, wherein the fastener core includes a round core, and wherein the shaft fastener component includes a cylinder shape.

16. The multi fan device of claim 2, further comprising a fan cable configured to enable power and control signals to be received by each plurality of fans, the fan cable electrically coupled to the second connector component.

17. The multi fan device of claim 16, wherein the plurality of fans comprise a first plurality of fans, a second plurality of fans, and a last plurality of fans, and wherein the first plurality of fans, the second plurality of fans, and the last plurality of fans are linearly disposed together, the fan cable is electrically coupled to the second connector component of the first plurality of fans, the first connector component of the first plurality of fans is electrically coupled to the second connector component of the second plurality of fans, and the first connector component of the second plurality of fans is electrically coupled to the second connector component of the last plurality of fans.

18. The multi fan device of claim 9, wherein the plurality of fans comprise a first plurality of fans, a second plurality of fans, and a last plurality of fans, and wherein the first plurality of fans, the second plurality of fans, and the last plurality of fans are linearly disposed together, the first fastener component of the first plurality of fans is fastened to the second fastener component of the second plurality of fans, and the first fastener component of the second plurality of fans is fastened to the second fastener component of the last plurality of fans.

19. The multi fan device of claim 1, wherein the fan comprises a plurality of blades and a fan motor, the plurality of blades extend outward from the fan motor, the fan motor electrically coupled to the connector assembly.
